(19) United States
(12) Patent Application Publication
(10) Pub. No.: US 2001/0016416 A1
(43) Pub. Date: Aug. 23, 2001

(54) Method for fabricating contact plug

(75) Inventor: Kyu-Hyun Kim, Choongcheongbuk-Do (KR)

Correspondence Address: MORGAN, LEWIS & BOCKIUS, 1800 M STREET NW, WASHINGTON, DC, 20036-5869, US

(73) Assignee: Hyundai Electronics Industries Co., Ltd.

(21) Appl. No.: 09/770,304

(22) Filed: Jan. 29, 2001

(30) Foreign Application Priority Data
Feb. 8, 2000 (KR) 2000/5759

(51) Int. Cl. H01L 21/4763; H01L 21/44

(52) U.S. Cl. 438/637; 438/643; 438/648; 438/653; 438/656

(57) ABSTRACT

A method for fabricating a contact plug that has a superior step coverage and does not have internal micro-cracks, including a first step for forming an insulating film including a contact hole on a silicon substrate, a second step for forming a Ti film in the contact hole, a third step for forming a TiN film on the Ti film, and a fourth step for repeatedly performing the second and third steps.

### CROSS-REFERENCE TO RELATED APPLICATIONS

This application claims priority to Korean Patent Application No. 2000/5759, filed on Feb. 8, 2000, the disclosure of which is incorporated by reference herein in its entirety.

### BACKGROUND OF THE INVENTION

1. Field of the Invention

The present invention relates to a method for fabricating a semiconductor device, and in particular to a method for fabricating a contact plug that has a superior step coverage and does not have internal micro-cracks.

2. Description of the Background Art

Semiconductor devices can be formed on a silicon substrate having P+ type or N+ type doped regions. The doped regions must be electrically connected to form an electrical circuit. Accordingly, a conductive layer that includes a metal or a doped polycrystalline silicon is deposited and patterned. In a conventional method for fabricating a semiconductor device, an insulating layer formed on a wafer is patterned and etched to form a contact hole. A contact plug and an interconnecting lead are formed by a conductive material.

It is known to use W to form a contact plug. However, there has been recent interest in using TiN instead of W as a material in the contact plug. TiN can better fill a narrow contact hole or via hole since TiN has a superior step coverage as compared to W. In addition, since TiN itself serves as a diffusion barrier layer, it is unnecessary to deposit an additional diffusion barrier layer consisting of Ti/TiN, and therefore the manufacturing process of the contact plug is simplified.

FIGS. 1(a) to 1(d) illustrate the sequential steps of the conventional method for fabricating the Ti/TiN contact plug.

As shown in FIG. 1(a), an insulating film 2 including silicon oxide (SiO₂) is deposited on a silicon substrate 1 that includes a doped region (not shown). A photoresist film (not shown) is spread on the insulating film 2, and patterned according to an exposure and developing process. A contact hole 10 is formed in the insulating film 2 by an etching process that uses the patterned photoresist film (not shown) as a mask. The silicon substrate 1 is oxidized forming a native oxide film 3 at the upper surface of the silicon substrate 1 exposed by the contact hole 10.

Thereafter, as depicted in FIG. 1(b), the native oxide film 3 shown in FIG. 1(a) is removed by a cleaning process.

As illustrated in FIG. 1(c), a Ti film 5 is deposited on the upper surface of the insulating film 2 and inside of the contact hole 10. The deposition of the Ti film 5 is performed at a temperature of approximately 650° C. The silicon and titanium react with each other and form a titanium silicide (TiSi₂) film 4 at an interface between the silicon substrate 1 and the Ti film 5.

As shown in FIG. 1(d), a TiN film 6 is formed thick on the Ti film 5 in order to fill the contact hole 10, thereby completing the fabrication of the contact plug.

However, when the contact plug is fabricated by forming the TiN film 6 thick, micro-cracks 20 form in the TiN film 6. The micro-cracks 20 are formed at grain boundaries due to stress generated from a nucleation step that is an initial stage of the deposition of the TiN to a grain transition step that leads to a bulk layer growth step. A number of disadvantages arise due to the formation of the micro-cracks 20.

First, after the formation of the contact plug, when a tungsten line is formed by depositing the tungsten according to the chemical vapor deposition using WF₆, the WF₆ gas can penetrate into the TiN film through the micro-cracks and react with the TiN film.

Second, the WF₆ gas penetrating into the TiN film can be diffused into the device and cause the deterioration of the electric characteristics of the device.

Third, when the micro-cracks are formed in the TiN film, the TiN film cannot be operated as the diffusion barrier film.

### SUMMARY OF THE INVENTION

Accordingly, it is an object of the present invention to provide a method for fabricating a contact plug which has a sufficient step coverage to fill a narrow contact hole or via hole.

It is another object of the present invention to restrict the formation or generation of micro-cracks and thus prevent the deterioration of the characteristics of the device caused by the micro-cracks.

It is still another object of the present invention to simplify the process of fabricating a contact plug by removing the necessity of an additional or specific diffusion barrier layer.

In order to achieve these and other objects of the present invention, there is provided a method for fabricating a contact plug, including: a first step for forming an insulating film including a contact hole on a silicon substrate; a second step for forming a Ti film in the contact hole; a third step for forming a TiN film on the Ti film; and a fourth step for repeatedly performing the second and third steps a few times. In addition, the method for fabricating the contact plug may further include a step for nitriding a surface of the Ti film between the second step and the third step, in order to enhance adhesion between the Ti film and the TiN film.

### BRIEF DESCRIPTION OF THE DRAWINGS

The accompanying drawings, which are incorporated herein and constitute part of this specification, illustrate specific preferred embodiments of the present invention, and, together with the general descriptions given above and the detailed descriptions given below, serve to explain features of the present invention.

FIGS. 1(a) to 1(d) illustrate the sequential steps of a conventional method for fabricating a Ti/TiN contact plug; and

FIGS. 2(a) to 2(f) illustrate the sequential steps of a method for fabricating a Ti/TiN contact plug in accordance with a preferred embodiment of the present invention.

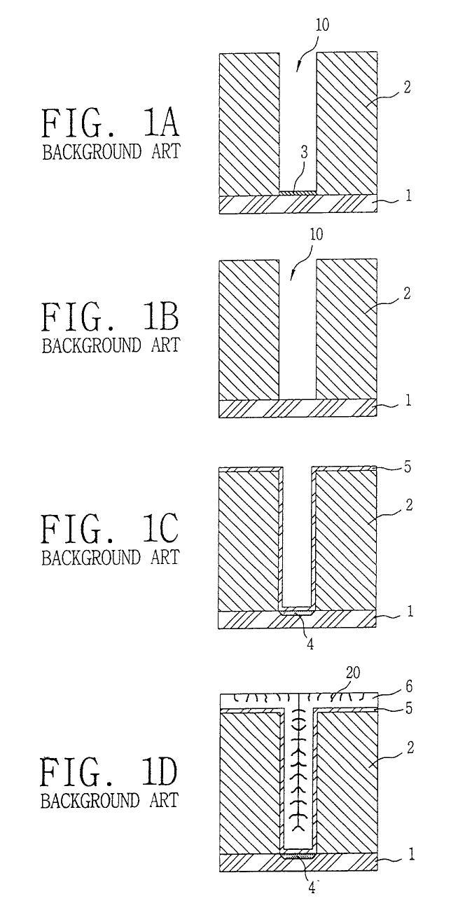

### DETAILED DESCRIPTION OF THE PREFERRED EMBODIMENTS

An example of a structure of a semiconductor device and a fabrication method thereof in accordance with the present invention will now be described in detail with reference to the accompanying drawings.

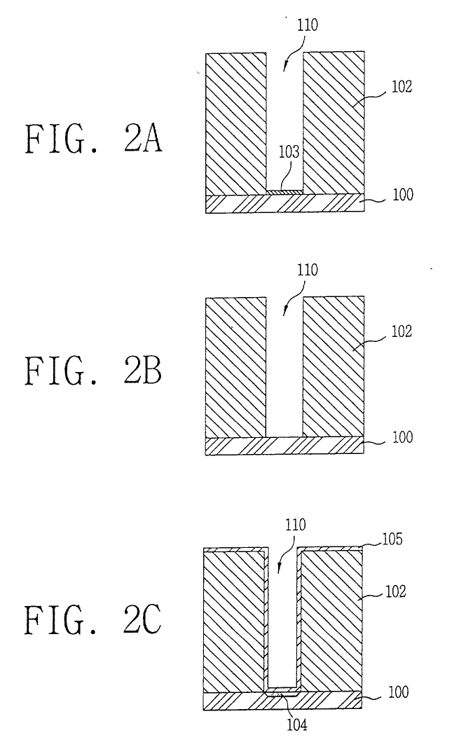

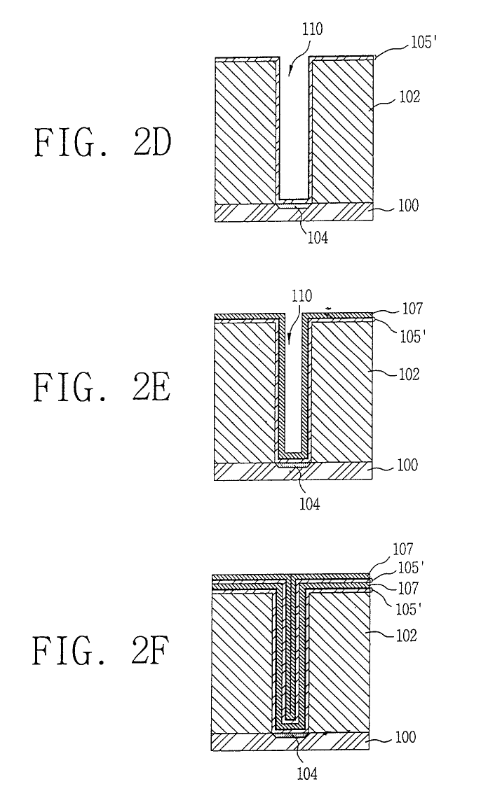

FIGS. 2(a) to 2(f) illustrate the sequential steps of a method for fabricating a contact plug in accordance with a preferred embodiment of the present invention.

As shown in FIG. 2(a), an insulating film 102 including silicon oxide (SiO₂) is deposited on a silicon substrate 100 that includes a doped region (not shown). A photoresist film (not shown) is spread on the insulating film 102, and patterned by an exposure and developing process. The patterned photoresist film (not shown) is used as a mask in an etching process to form a contact hole 110 in the insulating film 102. A native oxide film 103 is formed on an upper surface of the silicon substrate 100 that is exposed by the contact hole 110.

As illustrated in FIG. 2(b), the native oxide film 103 is removed by a cleaning process. A solution made by adding a predetermined ratio of detergent into a buffered oxide etchant (BOE) where HF and NH₄F are mixed can be used as a cleaning solution. The cleaning process can be carried out by using a spin etch.

As shown in FIG. 2(c), a Ti film 105 is deposited on an upper surface of the insulating film 102 and inside of the contact hole 110. The deposition of the Ti film 105 can be performed by a variety of methods. The Ti film 105 can be deposited according to the chemical vapor deposition (CVD). The Ti film 105 can also be deposited by a plasma enhanced chemical vapor deposition (PECVD). A variety of gases that include Ti can be used as a source gas for growing the Ti film 105. The source gas can include TiCl₄. A thickness of the Ti film 105 can be less than about 100 Å. The deposition of the Ti film 105 can be performed at a temperature between about 500° C. and about 800° C., and can be preferably about 650° C. The silicon and titanium react to form a titanium silicide (TiSi₂) film 104 at an interface between the silicon substrate 100 and the Ti film 105. The titanium silicide film 104 forms an ohmic contact between the silicon substrate 100 and the Ti film 105.

The titanium silicide film described above can be formed by simultaneously depositing and annealing the Ti film 105, or can be formed by annealing the Ti film 105 after the deposition of the Ti film.

Thereafter, as illustrated in FIG. 2(d), a gas that includes nitrogen is provided. The surface of the Ti film 105 is nitrided, thereby forming a Ti film 105′ having a nitrided surface or a nitride film. The surface of the Ti film 105 can be nitrided by using the gas including NH₃. The flow of NH₃ can be between about 800 and about 1200 sccm, and can be preferably about 1000 sccm. A temperature of the chamber where the nitriding reaction takes place can be controlled, and can be at least about 600° C., and can be preferably at least about 680° C. The nitride film formed on the surface of the Ti film enhances adhesion between a deposited TiN film 107 and the Ti film 105′. The nitride film also prevents the Ti film 105′ from being etched by a source gas used for depositing the TiN film 107.

As shown in FIG. 2(e), the TiN film 107 is deposited on the Ti film 105′ having the nitrided surface. The deposition of the TiN film 107 can be performed by a variety of methods. The TiN film 107 can be deposited according to a process of chemical vapor deposition (CVD). The TiN film 107 can also be deposited by plasma enhanced chemical vapor deposition (PECVD). Various gases that include Ti and N can be used as a source gas for growing the TiN film 107. The source gas can include TiCl₄ and NH₃. A thickness of the TiN film 107 can be about less than a critical thickness at which micro-cracks start to develop due to an accumulation of stress in the TiN film 107 during deposition. The thickness of the TiN film 107 can also be less than about 100 Å. The deposition of the TiN film 107 can be carried out at a temperature between about 500° C. and about 800° C., and can be approximately 650° C.

As illustrated in FIG. 2(f), steps shown in FIGS. 2(c) and 2(e) are repeated, thereby alternately forming the Ti film 105′ having the nitrided surface and the TiN film 107. The steps shown in FIGS. 2(c) and 2(e) can be repeated from 2 to 6 times. The Ti film 105′ having the nitrided surface and the TiN film 107 can be alternately deposited until the contact hole 105 is filled so that a film closer to the silicon substrate 100 can be the Ti film 105′ and an uppermost film can be the TiN film 107.

In accordance with the method for fabricating the contact plug of the present invention, the thickness of the TiN film is about less than the critical thickness at which the micro-cracks start to form, thereby preventing the micro-cracks from forming in the TiN film. As a result, the present invention prevents the undesired effects that are caused by the micro-cracks on the characteristics of the device and during the fabrication process.

In addition, according to the present invention, the surface of the Ti film is nitrided before the formation of the TiN film, thereby enhancing adhesion between the Ti film and the TiN film and preventing the Ti film from being etched by the source gas that is used to grow the TiN film.

Furthermore, in accordance with the present invention, the contact plug replaces the conventional TiN contact plug and overcomes the disadvantages of the conventional contact plug. A narrow contact hole or via hole can be filled since TiN has a superior step coverage. The fabrication process is simplified since the TiN film operates as a diffusion barrier film and therefore it is not necessary to deposit the diffusion barrier film in advance.

As the present invention may be embodied in several forms without departing from the spirit or essential characteristics thereof, it should also be understood that the above-described embodiment is not limited by any of the details of the foregoing description, unless otherwise specified, but rather should be construed broadly within its spirit and scope as defined in the appended claims, and therefore all changes and modifications that fall within the metes and bounds of the claims, or equivalents of such metes and bounds are therefore intended to be embraced by the appended claims.

What is claimed is:

1. A method for fabricating a contact plug, comprising:
forming an insulating film on a silicon substrate, the insulating film including a contact hole;
forming a Ti film in the contact hole;
forming a TiN film on the Ti film; and
repeating the forming of a Ti film in the contact hole step and the forming of a TiN film on the Ti film step.

2. The method according to claim 1, further comprising a cleaning process of removing a native oxide film, wherein the cleaning process occurs before forming a Ti film in the contact hole.

3. The method according to claim 1, wherein forming a Ti film in the contact hole includes forming a thickness of the Ti film to less than about 100 Å.

4. The method according to claim 1, wherein forming a TiN film on the Ti film includes forming a thickness of the TiN film to less than about a critical thickness at which micro-cracks are formed in the TiN film.

5. The method according to claim 4, wherein a thickness of the TiN film is less than about 1000 Å.

6. The method according to claim 1, further comprising nitriding the Ti film, wherein nitriding occurs between the forming of a Ti film in the contact hole and the forming of a TiN film on the Ti film.

7. The method according to claim 6, wherein nitriding the Ti film occurs at a temperature of at least about 600° C.

8. The method according to claim 6, wherein nitriding the Ti film includes using an NH₃ gas.

9. The method according to claim 8, wherein a flow of the NH₃ gas is between about 800 and about 1200 sccm.

10. The method according to claim 1, wherein the Ti film and the TiN film are formed by chemical vapor deposition (CVD).

11. The method according to claim 10, wherein the chemical vapor deposition comprises a plasma enhanced chemical vapor deposition (PECVD).

12. The method according to claim 10, wherein the chemical vapor deposition includes a source gas of TiCl₄.

13. The method according to claim 1, wherein forming a Ti film in the contact hole includes forming a silicide by one of either simultaneously depositing and annealing the Ti film, and by annealing the Ti film after a deposition thereof and by reacting the silicon substrate with the Ti film.

14. The method according to claim 1, wherein, in forming a Ti film in the contact hole, the Ti film is formed at a temperature of between about 500 and about 800° C.

15. The method according to claim 1, wherein, in forming a TiN film on the Ti film, the TiN film is formed at a temperature of between about 500 and about 800° C.

16. The method according to claim 1, wherein the repeating is performed so that a multi-layer film of Ti and TiN about completely fills the contact hole.

17. The method according to claim 1, wherein the repeating occurs between two and six times.
